(19) United States
(12) Patent Application Publication
(10) Pub. No.: US 2026/0344435 A1
(43) Pub. Date: Oct. 29, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Yu Jung JUNG, Icheon-si Gyeonggi-do (KR); Da Yung BYUN, Icheon-si Gyeonggi-do (KR)

(73) Assignee: SK hynix Inc., Icheon-si Gyeonggi-do (KR)

(21) Appl. No.: 19/374,851

(22) Filed: Oct. 30, 2025

(30) Foreign Application Priority Data
Apr. 25, 2025 (KR) 10-2025-0054595

(51) Int. Cl. H10W 42/00; H10W 70/65; H10W 70/685; H10W 74/10; H10W 90/00

(52) U.S. Cl. CPC H10W 42/00; H10W 70/65; H10W 70/685; H10W 74/131; H10W 90/401

(57) ABSTRACT

A semiconductor device includes a semiconductor chip and a chip guard around the semiconductor chip in which the chip guard comprises a plurality of pillars arranged in a first direction and extending in a second direction crossing the first direction, a first projection extending from plurality of pillars in the first direction, and a second projection extending from the plurality of pillars and spaced apart from the first projection in the second direction.

### CROSS REFERENCE TO RELATED APPLICATION

The present application claims priority under 35 U.S.C. §119(a) to Korean patent application number 10-2025-0054595 filed on Apr. 25, 2025, in the Korean Intellectual Property Office, the entire contents of which application is incorporated herein by reference.

### BACKGROUND

### 1. Technical Field

The present disclosure relates to a semiconductor device and a method of manufacturing a semiconductor device, including but not limited to a semiconductor device including a chip guard.

### 2. Related Art

Using a semiconductor integration process, a plurality of chip areas are formed on a semiconductor substrate. The plurality of chip areas are separated by a scribe lane area as a boundary. By separating the chip areas using a cutting process, a plurality of semiconductor chips are fabricated.

A chip guard surrounding a chip area is formed to protect an integrated circuit within the chip area. For example, the chip guard is arranged to surround the chip area. The chip guard may deter defect-inducing factors that occur outside the chip area and are transferred or spread inside the chip area.

### SUMMARY

According to an embodiment, a semiconductor device may include a semiconductor chip, and a chip guard around the chip area, wherein the chip guard comprises a plurality of pillars arranged in a first direction and extending in a second direction crossing the first direction, a first projection extending from the plurality of pillars in the first direction, and a second projection extending from the plurality of pillars and spaced apart from the first projection in the second direction.

According to an embodiment, a method of manufacturing a semiconductor device may include forming a stack including sacrificial layers alternately stacked with interlayer insulating layers in a chip area and a guard area around the chip area, forming openings extending through the stack and spaced apart in the guard area, etching the sacrificial layers exposed through the openings to form recesses adjacent to the openings, and forming a chip guard within the openings and the recesses.

### BRIEF DESCRIPTION OF THE DRAWINGS

FIG. 1 is a diagram illustrating structure of a semiconductor device according to an embodiment of the present disclosure;

FIGS. 2A to 2E are diagrams illustrating structure of a chip guard according to an embodiment of the present disclosure;

FIGS. 3A to 3D are cross-sectional views of a chip guard formed utilizing a manufacturing method of a chip guard according to an embodiment of the present disclosure;

FIGS. 4A and 4B are diagrams illustrating a chip guard coupled to lower wiring lines according to an embodiment of the present disclosure;

FIG. 5 is a diagram illustrating chip guards formed in a dual structure according to an embodiment of the present disclosure;

FIG. 6 is a diagram illustrating a memory card system according to an embodiment of the present disclosure; and

FIG. 7 is a diagram illustrating a solid state drive (SSD) system including a memory device according to an embodiment of the present disclosure.

### DETAILED DESCRIPTION

The present disclosure describes a semiconductor device and a method of manufacturing the semiconductor device that can reduce stress applied to the semiconductor device using a chip guard.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “connected” or “coupled” to another element, the elements may be connected or coupled directly or through at least one intervening element between the elements. When two elements are identified as “directly connected” or “directly coupled,” one element is directly connected or directly coupled to the other element without an intervening element between the two elements.

Terms such as “vertical,” “horizontal,” “top,” “bottom,” “overlap,” “on,” “side,” “upper,” “lower,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas. The drawings are not necessarily drawn to scale and may include differing quantities of various structures between the cross-sectional views and corresponding plan views, and complete versions of some structures are not shown between the cross-sectional views and corresponding plan views.

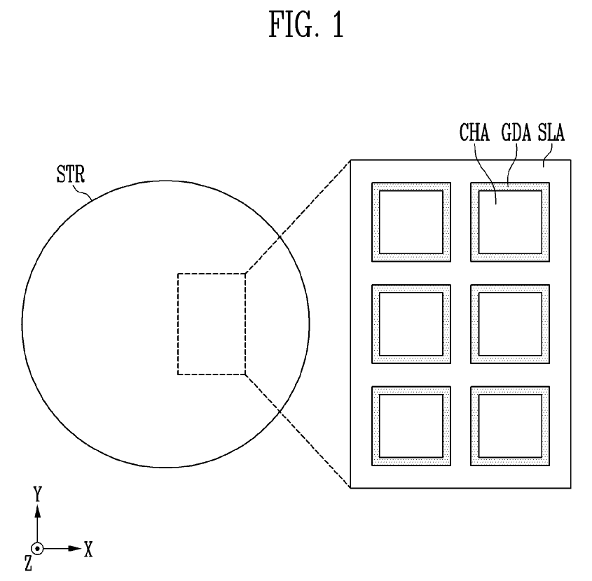

FIG. 1 is a diagram illustrating structure of a semiconductor device according to an embodiment of the present disclosure.

The semiconductor device includes a structure STR. For example, the structure STR includes at least one of a substrate, such as a silicon wafer, a SiGe wafer, or a SOI wafer, and a stack formed on the substrate.

Referring to FIG. 1, the structure STR has chip areas CHA, guard areas GDA, and a scribe lane area SLA. For example, the structure STR includes the chip areas CHA, the guard areas GDA surrounding corresponding chip areas CHA, and the scribe lane area SLA surrounding the guard areas GDA.

The chip areas CHA are areas where semiconductor chips are formed. The chip areas CHA re arranged along an X direction and a Y direction. By performing a semiconductor integration process on the chip areas CHA, semiconductor chips are formed. The semiconductor chips formed within the plurality of chip areas CHA within the structure STR may be substantially operations. By separating the structure STR by the chip areas CHA after the semiconductor integration process on the substrate is completed, the chip areas CHA are separated into individual semiconductor chips.

Each of the guard areas GDA is adjacent to a corresponding chip area CHA. Each of the guard areas GDA is located along a periphery of the corresponding chip area CHA. Each of the guard areas GDA may surround a corresponding chip area. For example, the guard areas GDA may be formed within a predetermined distance of boundaries of the chip areas CHA. When the chip region CHA has a rectangular shape in a plane, the guard area GDA may have a rectangular frame shape in a plane with an open or center area to surround the periphery of the chip region CHA. An outer surface of the chip area CHA may contact an inner surface of the guard area GDA.

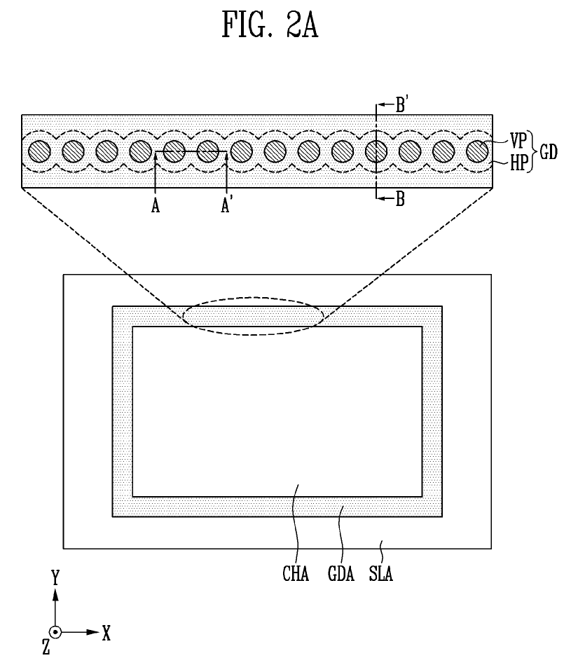

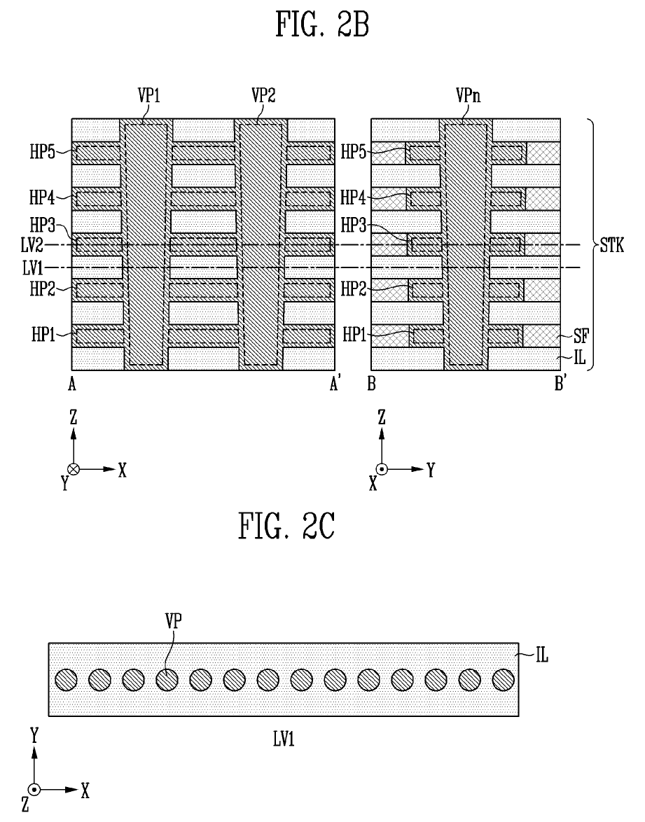

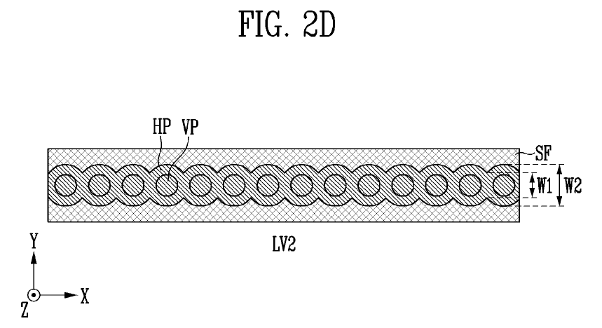

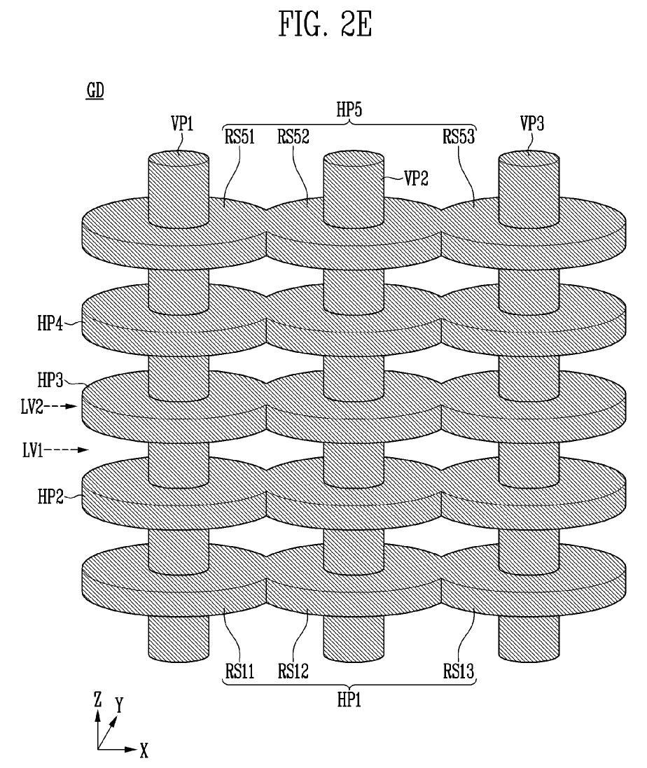

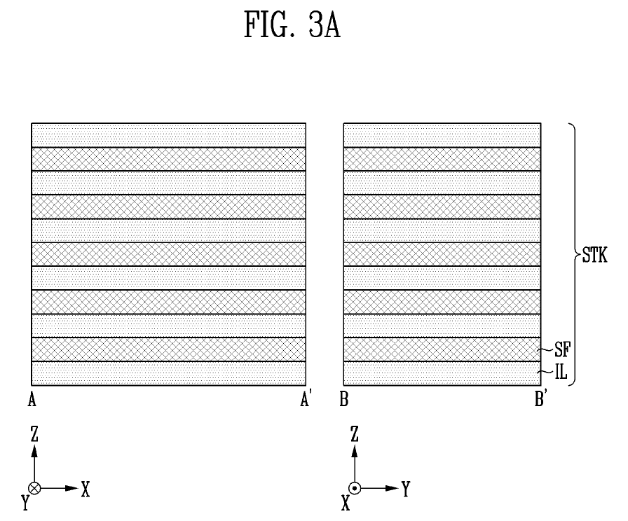

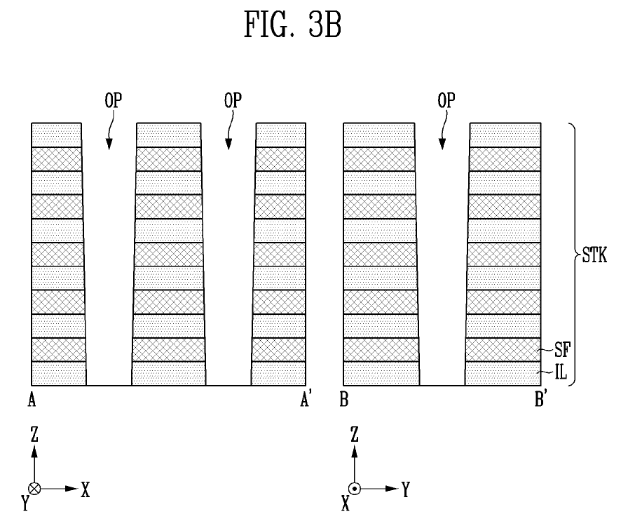

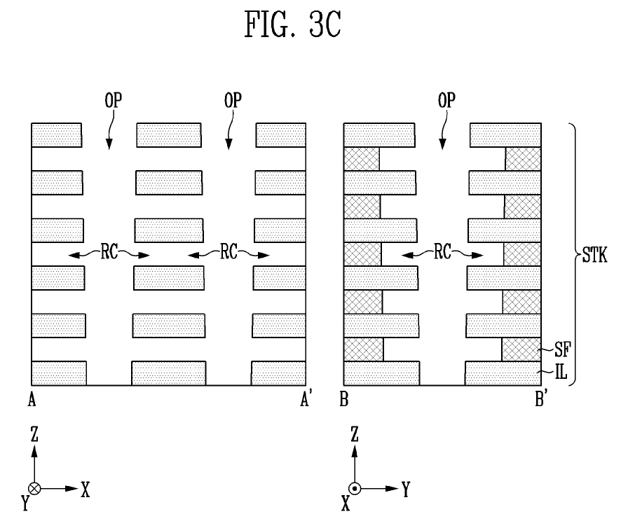

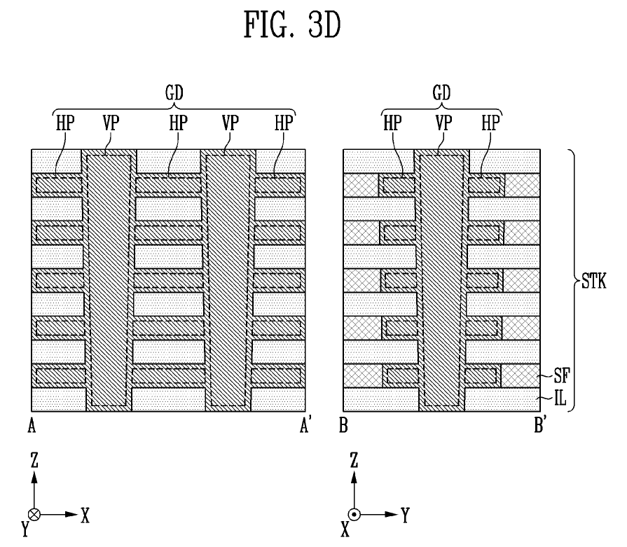

A chip guard is formed within the guard areas GDA. The chip guard may prevent moisture or oxygen from penetrating from outside of the chip area CHA to inside of the chip area CHA. Chip guards may reduce interference between dies in a packaging process performed after the chip areas CHA are separated into individual semiconductor chips. The form and method of manufacturing the chip guard formed within the guard area GDA are described with reference to FIGS. 2A-2E and 3A-3D.

The scribe lane area SLA is located outside of the chip areas CHA and the guard areas GDA. For example, the scribe lane area SLA is located between the chip areas CHA. After the semiconductor integration process is completed, the scribe lane area SLA may be cut away during a dicing process to separate the semiconductor chips. By cutting the structure STR along the scribe lane area SLA, the chip areas CHA are separated from each other. The separated semiconductor chip includes one chip area CHA and one guard area GDA surrounding the chip area CHA. A sawing process using a blade, a laser process using a laser, or a stealth dicing process may be used as a process for cutting the structure STR. Electrical test patterns, process monitoring patterns, and alignment keys may be disposed in the scribe lane area SLA.

In FIG. 1, six chip areas CHA are shown for simplicity of illustration, although the present disclosure is not limited to this example. For example, the structure STR may include seven or more chip areas CHA, and the quantity of chip areas may vary. Although the present disclosure illustrates the chip areas CHA, the guard areas GDA, and the scribe lane area SLA separately for simplicity, and the chip areas CHA, the guard areas GDA, and the scribe lane area SLA might not be physically separated and may be continuously connected to each other. For example, the locations of the chip areas CHA, the guard areas GDA, and the scribe lane area SLA on the substrate may be arbitrarily determined.

FIGS. 2A-2E are diagrams illustrating structure of a chip guard GD according to an embodiment of the present disclosure. FIG. 2A is a plan view illustrating the layout of the chip guard GD located inside the guard area GDA. FIG. 2B is a cross-sectional view through line A-A’ and through line B-B’ of FIG. 2A. FIG. 2C is a plan view corresponding to a cross-section of a first level LV1 of FIG. 2B. FIG. 2D is a plan view corresponding to a cross-section of a second level LV2 of FIG. 2B. FIG. 2E is a perspective view illustrating a shape of the chip guard GD.

Referring to FIG. 2A, the guard area GDA is located between the chip area CHA and the scribe lane area SLA. The guard area GDA may be located at a periphery of the chip area CHA. The guard area GDA is disposed to surround the chip area CHA. For example, the chip area CHA may have a rectangular shape in a plane, and the guard area GDA may extend along a boundary of the chip area CHA.

The chip guard GD is formed within the guard area GDA. The chip guard GD may be located at the periphery of the chip area CHA. The chip guard GD may contact the chip area CHA. The chip guard GD may surround the chip area CHA. For example, outside the chip area CHA, the chip guard GD extends in the Y direction and the X direction to surround the chip area CHA.

The chip guard GD includes vertical pillars VP and horizontal projections HP. The vertical pillars VP are arranged along the X direction and the Y direction. The horizontal projections HP surround the vertical pillars VP.

Referring to FIG. 2B, a stack STK is located within the guard area GDA. The stack STK extends from the chip area CHA to the guard areas GDA. The stack STK includes sacrificial layers SF alternating with interlayer insulating layers IL in a Z direction. The interlayer insulating layers IL may include an oxide layer such as a silicon oxide layer. The sacrificial layers SF may include a material that is selectively etchable or removable in a subsequent process. The sacrificial layers SF may include a material having a different etch selectivity with respect to the interlayer insulating layers IL. For example, the sacrificial layers SF may include a nitride layer. The chip guard GD may extend through the stack STK in the Z direction.

The vertical pillars VP may each extend along the Z direction. The vertical pillars VP may each penetrate the stack STK. The vertical pillars VP may extend through the sacrificial layers SF and the interlayer insulating layers IL. In an embodiment, the width of each of the vertical pillars VP tapers toward the bottom of the vertical pillar. In an embodiment, the width of each of the vertical pillars VP does not vary in the Z direction.

The vertical pillars VP are arranged along the X direction as shown in FIG. 2. For example, the vertical pillars VP may include a first vertical pillar VP1, a second vertical pillar VP2, and an nth vertical pillar VPn arranged in the X direction. The vertical pillars VP1 and VP2 are spaced apart in the X direction. The chip guard GD includes the vertical pillars VP arranged in the Y direction similar to the vertical pillars VP arranged in the X direction.

The horizontal projections HP contact or extend from the vertical pillars VP. For example, a first horizontal projection HP1 contacts each of the first vertical pillar VP1, the second vertical pillar VP2, and so forth through the nth vertical pillar VPn. The first horizontal projection HP1 contacts a section of a side of the first vertical pillar VP1, a section of a side of the second vertical pillar VP2, and so forth through a section of a side of the nth vertical pillar VPn. The first horizontal projection HP1 extends from a side of the first vertical pillar VP1, a side of the second vertical pillar VP2, and so forth through a side of the nth vertical pillar VPn. The first horizontal projection HP1 surrounds each of at least a section of the first vertical pillar VP1, at least a section of the second vertical pillar VP2, and so forth through at least a section of the nth vertical pillar VPn. The first horizontal projection HP1 couples the first vertical pillar VP1, the second vertical pillar VP2, and so forth through the nth vertical pillar VPn to each other in the X direction.

The second horizontal projection HP2 contacts or extends from each of the first vertical pillar VP1, the second vertical pillar VP2, and so forth through the nth vertical pillar VPn. The second horizontal projection HP2 contacts a section of the side of the first vertical pillar VP1, a section of the side of the second vertical pillar VP2, and so forth through a section of the side of the nth vertical pillar VPn. The second horizontal projection HP1 extends from a side of the first vertical pillar VP1, a side of the second vertical pillar VP2, and so forth through a side of the nth vertical pillar VPn. The second horizontal projection HP2 surrounds each of at least a section of the first vertical pillar VP1, at least a section of the second vertical pillar VP2, and so forth through at least a section of the nth vertical pillar VPn. The second horizontal projection HP2 couples the first vertical pillar VP1, the second vertical pillar VP2, and so forth through the nth vertical pillar VPn to each other in the X direction.

The horizontal projections HP may couple the vertical pillars VP spaced apart in the X direction. For example, the horizontal projections HP1 to HP5 are disposed between the first vertical pillar VP1 and the second vertical pillar VP2 spaced apart in the X direction. The horizontal projections HP combined with the vertical pillars VP may have a ladder shape in the Z direction.

The horizontal projections HP extend between the stack STK and the sides of the vertical pillar VP. For example, the horizontal projections HP extend in the Y direction from the side of each of the n vertical pillars VPn.

The horizontal projections HP are spaced apart in the Z direction. For example, the horizontal projections HP include the first horizontal projection HP1 to the fifth horizontal projection HP5 arranged in the Z direction. The second horizontal projection HP2 is spaced apart from the first horizontal projection HP1 in the Z direction.

In an embodiment, each of the horizontal projections HP is located at a level corresponding to one of the sacrificial layers SF. The levels of the horizontal projections HP are substantially the same as the levels of the sacrificial layers SF. For example, the fifth horizontal projections HP1 to HP5 overlap with the sacrificial layers SF in the Y direction and the X direction. The horizontal projections HP are disposed at the levels where the sacrificial layers SF are located and not at the levels where the interlayer insulating layers IL are located. For example, no horizontal projections HP are formed at the first level LV1 where the interlayer insulating layer IL is located, and the third horizontal projection HP3 is formed at the second level LV2 where the sacrificial layer SF is located.

Outer surfaces of the horizontal projections HP contact the sacrificial layers SF. For example, the sides of the horizontal projections HP in the Y-direction contact the sacrificial layers SF. Top and bottom surfaces of the horizontal projections HP contact the interlayer insulating layers IL. For example, the top and bottom surfaces of the first horizontal projection HP1 may contact the interlayer insulating layers IL. The interlayer insulating layers IL are located between the horizontal projections HP. For example, an interlayer insulating layer IL is located between the first horizontal projection HP1 and the second horizontal projection HP2. The interlayer insulating layers IL protrude between the vertical pillars VP and parallel to the sacrificial layers SF.

FIG. 2C illustrates a layout of the guard area GDA at the first level LV1 where an interlayer insulating layer IL is located, and FIG. 2D illustrates a layout of the guard area GDA at the second level LV2 where a sacrificial layer SF is located.

Referring to FIG. 2C, the vertical pillars VP are spaced apart in the X direction. At the first level LV1, the interlayer insulating layer IL is disposed between the vertical pillars VP. At the first level LV1, the vertical pillars VP are separated by the interlayer insulating layer IL and may be formed in a straight line.

The sides of the vertical pillars VP may be curved. For example, each of the vertical pillars VP may have a circular or elliptical planar shape.

Referring to FIG. 2D, at the second level LV2, the horizontal projection HP, the third horizontal projection HP3 in this example, extends in the X direction. At the second level LV2, the horizontal projection HP is formed between the vertical pillars VP. At least a section of the horizontal projection HP is located between the vertical pillars VP. The horizontal projection HP contacts or extends from each of the vertical pillars VP. At the second level LV2, the vertical pillars VP are coupled to each other by the horizontal projection HP. The horizontal projection HP couples the vertical pillars VP to each other. For example, the horizontal projections HP electrically couple the vertical pillars VP to each other.

The horizontal projection HP have a curved surface in an embodiment. The outer surface of the horizontal projection HP includes a curved surface. The horizontal projection HP includes extensions projecting perpendicular to the side of the vertical pillars VP. The outer surface of the horizontal projection HP may include curved surfaces adjacent to the sacrificial layer SF. For example, the horizontal projection HP extends in the X direction and the Y direction, and the horizontal projection HP has curved surfaces on each side of the vertical pillars VP in the Y direction.

The horizontal projection HP has an outer width that varies between a first width W1 and a second width W2 in the Y direction. The second width W2 is larger than the first width W1. In this example, the outer width of the horizontal projection HP refers to the distance between outermost surfaces of the horizontal projection HP in the Y direction or a direction perpendicular to a direction in which the horizontal projection HP extends in a planar view. For example, in FIG. 2D, the horizontal projection HP extends in the X direction, and the outer width of the horizontal projection HP extends in the Y direction.

The horizontal projection HP has an outer width that includes the first width W1, the second width W2, and a continuous range of values between the first width W1 and the second width W2. For example, in FIG. 2D, the outer width of the horizontal projection HP has a minimum value of the first width W1 and a maximum value of the second width W2. In addition to the first width W1 and the second width W2, the horizontal projection HP may have a width of any value between the first width W1 and the second width W2. The outer width of the horizontal projection HP may include the first width W1 and the second width W2.

Referring to FIG. 2E, the chip guard GD includes the first vertical pillar VP1 to the third vertical pillar VP3 and the horizontal projections HP1 to HP5. The vertical pillars VP1 to VP3 refer to any group of three vertical pillars VP arranged consecutively in the X direction in FIGS. 2C and 2D. The horizontal projections HP1 to HP5 correspond to the horizontal projections HP1 to HP5 of FIG. 2B.

In an embodiment, the vertical pillars VP each have a cylindrical shape extending in the Z direction. The vertical pillars VP may be formed with equal widths or diameters in the Y direction. The vertical pillars VP are spaced apart consecutively in the X direction. For example, the second vertical pillar VP2 is spaced apart from the first vertical pillar VP1 in the X direction, and the third vertical pillar VP3 is spaced apart from the second vertical pillar VP2 in the X direction.

Each of the horizontal projections HP extends in the X direction. Each of the horizontal projections HP contacts or is integrated with the vertical pillars VP. For example, the first horizontal projection HP1 includes a disc or ring RS11 contacting or extending from the side of the first vertical pillar VP1. The first horizontal projection HP1 includes a ring RS12 contacting or extending from the side of the second vertical pillar VP2. The first horizontal projection HP1 includes a ring RS13 contacting or extending from a side of the third vertical pillar VP3. The rings RS11 to RS13 surround sections of the corresponding sides of the vertical pillars VP1 to VP3. The rings RS11 to RS13 may each have a circular, oval, or square ring shape. The rings RS11 to RS13 may each have a cylindrical shape. The first horizontal projection HP1 include the rings RS11 to RS13 interconnected with or intersecting each other. The first horizontal projection HP1 has a form in which the cylinders or rings arranged in the X direction and extend from each other. The outer surface and the inner surface of the first horizontal projection HP1 may include curved surfaces.

The horizontal projections HP1 to HP5 are spaced apart and stacked in the Z direction. The fifth horizontal projections HP1 to HP5 may be similar structures or may be formed having the same shape with a difference in length. For example, the fifth horizontal projection HP5 includes a ring RS51 contacting the side of the first vertical pillar VP1. The fifth horizontal projection HP5 includes a ring RS52 contacting the side of the second vertical pillar VP2. The fifth horizontal projection HP5 includes a ring RS53 contacting the side of the third vertical pillar VP3. The rings RS51 to RS53 surround sections of the sides of the vertical pillars VP1 to VP3. The rings RS51 to RS53 may each have a circular, oval, or square ring shape. The rings RS51 to RS53 may each have a cylindrical shape. The fifth horizontal projection HP5 includes the rings RS51 to RS53 interconnected with or intersecting each other. The fifth horizontal projection HP5 has a form in which the cylinders or rings are arranged in the X direction and extend from each other. The outer surface and inner surface of the fifth horizontal projection HP5 may include curved surfaces.

The chip guard GD may include a conductive layer. For example, the chip guard GD may include at least one of tungsten (W), cobalt (Co), nickel (Ni), molybdenum (Mo), silicon (Si), or polysilicon (poly-Si).

The vertical pillars VP are coupled to each other via the horizontal projections HP. The horizontal projections HP couple the vertical pillars VP that are spaced apart in the X direction. In an embodiment, the vertical pillars VP are electrically coupled to each other via the horizontal projections HP.

The horizontal projections HP are coupled to each other via the vertical pillars VP. The vertical pillars VP couple the horizontal projections HP that are spaced apart in the Z direction. In an embodiment, the horizontal projections HP re electrically coupled to each other via the vertical pillars VP.

The vertical pillars VP and the horizontal projections HP as shown in FIGS. 2A-2E correspond to a part of the chip guard GD for simplicity of illustration, and the quantities of vertical pillars VP and horizontal projections HP are not limited to quantities shown in FIGS. 2A-2E.

FIGS. 3A-3D are cross-sectional views of a chip guard formed utilizing a method of manufacturing a chip guard according to an embodiment of the present disclosure. FIGS. 3A-3D are cross-sectional views through lines A-A’ and B-B’ of FIG. 2A.

Referring to FIG. 3A, the stack STK including the sacrificial layers SF alternately stacked with the interlayer insulating layers IL in the guard area GDA is formed. For example, the interlayer insulating layers IL may include an oxide layer, such as a silicon oxide layer. The sacrificial layers SF may include a material that is selectively removable in a subsequent process. The sacrificial layers SF may include a material having a different etch selectivity ratio with respect to the interlayer insulating layers IL. For example, the sacrificial layers SF may include nitride. While FIG. 3A illustrates the stack STK formed in the guard area GDA, the stack STK including the alternating sacrificial layers SF and interlayer insulating layers IL is formed in the chip area CHA.

Referring to FIG. 3B, openings OP are formed through the stack STK. The stack STK in the guard area GDA may be etched to form the openings OP. Each of the openings OP extend in the Z direction. The openings OP extend through the sacrificial layers SF and the interlayer insulating layers IL. The openings OP are spaced apart in the X direction.

Referring to FIG. 3C, the sacrificial layers SF are etched through the openings OP. The sacrificial layers SF are etched from the sides of the sacrificial layers SF exposed through the openings OP. The sacrificial layers SF are selectively etched among the sacrificial layers SF and the interlayer insulating layers IL exposed through the openings OP. While the sacrificial layers SF are etched, the interlayer insulating layers IL might not be etched. For example, HF or buffered oxide etchant (BOE) may be used to selectively etch the sacrificial layers SF.

At least some of the sacrificial layers SF are removed to form recesses RC. The recesses RC extend from the openings OP towards the remaining sacrificial layers SF. The openings OP are open to each other through the recesses RC. For example, the amount of the sacrificial layers SF that is etched is determined such that a segment of each of the sacrificial layers SF located between the openings OP is removed.

Referring to FIG. 3D, the chip guard GD is formed within the openings OP and the recesses RC. The chip guard GD fills the openings OP and the recesses RC. The vertical pillars VP of the chip guard GD are located inside the openings OP, and the horizontal projections HP of the chip guard GD are located inside the recesses RC. The chip guard GD may include a conductive layer. The vertical pillars VP of the chip guard GD may be separately formed from the horizontal projections HP or the vertical pillars VP of the chip guard GD may be unitarily or continuously formed from the horizontal projections HP. The openings OP and the recesses RC may be filled with a conductive material to form the chip guard GD.

The chip guard GD may prevent or reduce the ingress of harmful substances, H₂O or O₂, from the outside of the chip areas CHA to the inside of the chip areas CHA. The chip guard GD may reduce interference between semiconductor chips during a packaging process that is performed when the chip areas CHA are separated into semiconductor chips.

In an embodiment, the chip guard GD includes the horizontal projections HP that are disposed to correspond to selected levels of the vertical pillars VP. Compared to the example when the sacrificial layers SF and the interlayer insulating layers IL are etched through the openings OP, the volume of the chip guard GD may be reduced when the sacrificial layers SF are selectively etched according to an embodiment. The stress on the structure STR due to the conductive material filling the chip guard GD may be reduced.

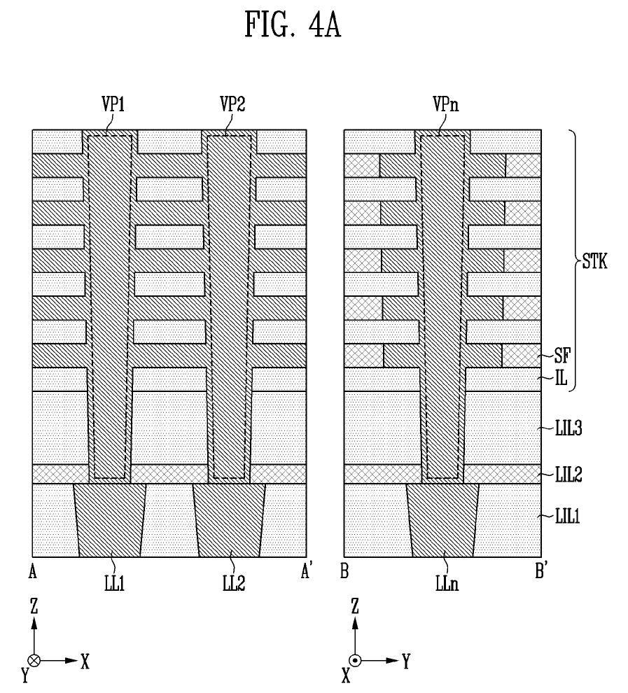

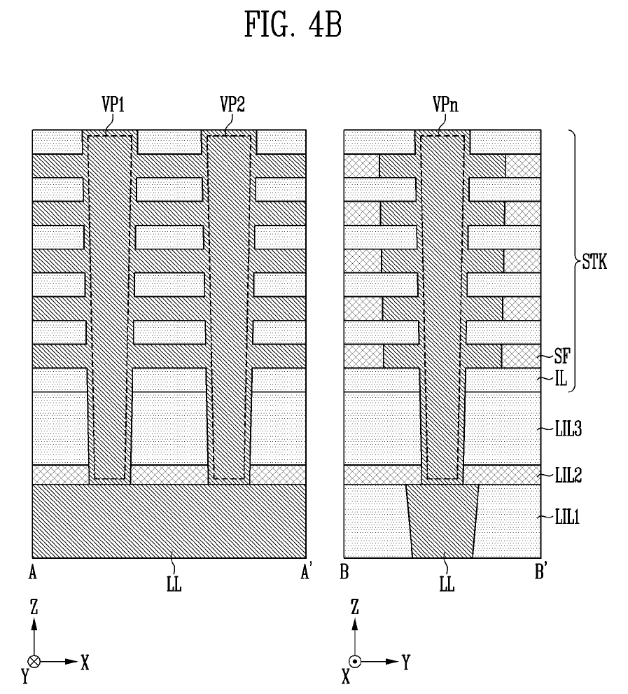

FIGS. 4A and 4B are diagrams illustrating a chip guard coupled to lower wiring lines according to an embodiment of the present disclosure.

Referring to FIGS. 4A and 4B, a first lower insulating layer LIL1 to a third lower insulating layer LIL3 are disposed at a lower end of the stack STK. The insulating layers LIL1 to LIL3 are formed sequentially in the Z direction. The lower insulating layers LIL1 and LIL3 may include a material similar to the material of the interlayer insulating layers IL. The second lower insulating layer LIL2 may include a material similar to the material of the sacrificial layers SF. The vertical pillars VP included in the chip guard GD extend through the third lower insulating layer LIL3 and the second lower insulating layer LIL2 in an embodiment.

Referring to FIG. 4A, a plurality of lower wiring lines LL1 to LLn are disposed inside the first lower insulating layer LIL1. The plurality of lower wiring lines LL1 to LLn are spaced apart in the X direction. The plurality of lower wiring lines LL1 to LLn extend through the first lower insulating layer LIL1. The plurality of lower wiring lines LL1 to LLn may each include a conductive material.

The vertical pillars VP1 to VPn contact the lower wiring lines LL1 to LLn, respectively. The vertical pillars VP1 to VPn are coupled to the lower wiring lines LL1 to LLn, respectively. The lower wiring lines LL1 to LLn are coupled to each other via the chip guard GD.

Referring to FIG. 4B, one lower wiring line LL is disposed inside the first lower insulating layer LIL1. The lower wiring line LL extends in the X direction. The lower wiring line LL extends through the first lower insulating layer LIL1. The lower wiring line LL may include a conductive material.

The vertical pillars VP1 to VPn contact the lower wiring line LL. The vertical pillars VP1 to VPn are coupled in common to the lower wiring line LL.

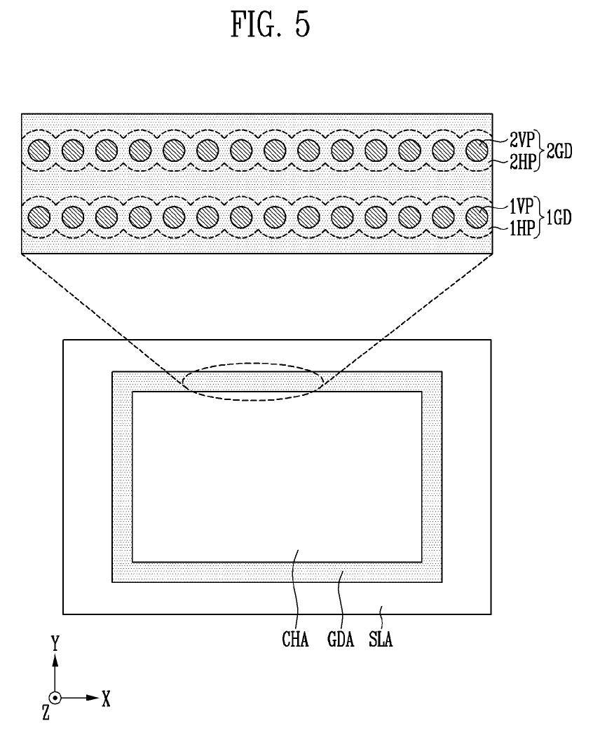

FIG. 5 is a diagram illustrating chip guards formed in a dual structure according to an embodiment of the present disclosure.

Referring to FIG. 5, two or more chip guards are located inside the guard area GDA in an embodiment. For example, a first chip guard 1GD and a second chip guard 2GD are disposed in parallel within the guard area GDA. The first chip guard 1GD is located between the chip area CHA and the second chip guard 2GD. The chip guards 1GD and 2GD may each surround the chip area CHA. The second chip guard 2GD surrounds the first chip guard 1GD and the chip area CHA.

The first chip guard 1GD and the second chip guard 2GD may have substantially the same shape. For example, the first chip guard 1GD includes vertical pillars 1VP and horizontal projections 1HP contacting or extending from the vertical pillars 1VP, and the second chip guard 2GD includes vertical pillars 2VP and horizontal projections 2HP contacting or extending from the vertical pillars 2VP. The vertical pillars 1VP of the first chip guard 1GD and the vertical pillars 2VP of the second chip guard 2GD correspond to the vertical pillars VP as described in FIGS. 2A-2E. The horizontal projections 1HP of the first chip guard 1GD and the horizontal projections 2HP of the second chip guard 2GD correspond to the horizontal projections HP as described in FIGS. 2A-2E.

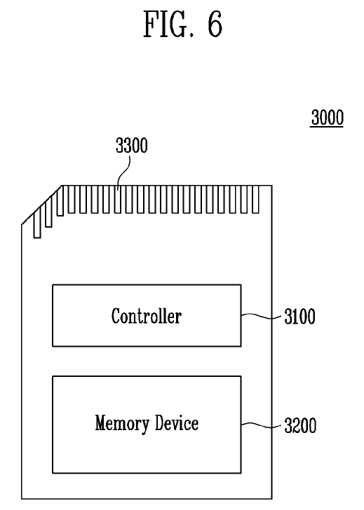

FIG. 6 is a block diagram illustrating a memory card system 3000 according to an embodiment of the present disclosure.

Referring to FIG. 6, the memory card system 3000 includes a controller 3100, a memory device 3200, and a connector 3300.

The controller 3100 is coupled to the memory device 3200. The controller 3100 accesses the memory device 3200. For example, the controller 3100 controls program operations, read operations, erase operations, and background operations of the memory device 3200. The controller 3100 provides an interface between the memory device 3200 and a host. The controller 3100 may drive firmware for controlling the memory device 3200. For example, the controller 3100 may include components such as a Random Access Memory (RAM), a processing unit, a host interface, a memory interface, and an ECC circuit.

The controller 3100 communicates with an external device through the connector 3300. The controller 3100 communicates with an external device such as a host based on a specific communication protocol. For example, the controller 3100 communicates with the external device using at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) protocols. For example, the connector 3300 may be configured according to at least one of the various communication protocols.

The memory device 3200 includes a plurality of memory cells and corresponds to one of the chip areas CHA of FIG. 1.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM or SMC), a memory stick, a multimedia card (MMC, RS-MMC, MMCmicro, or eMMC), an SD card (SD, miniSD, microSD, or SDHC), a universal flash storage (UFS), and the like.

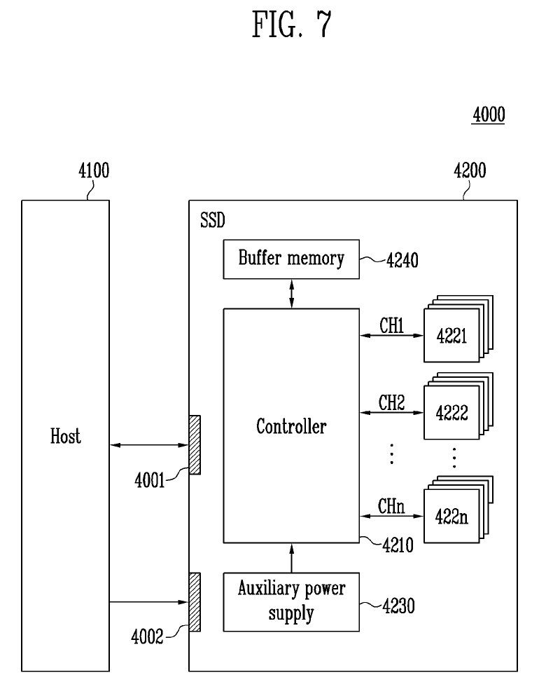

FIG. 7 is a block diagram illustrating a solid state drive (SSD) system 4000 including a memory device according to an embodiment of the present disclosure.

Referring to FIG. 7, the SSD system 4000 includes a host 4100 and an SSD 4200. The SSD 4200 exchanges signals with the host 4100 through a signal connector 4001 and receives power through a power connector 4002. The SSD 4200 includes a controller 4210, a plurality of memory devices 4221 to 422n, an auxiliary power supply 4230, and buffer memory 4240.

The controller 4210 controls the plurality of memory devices 4221 to 422n in response to signals received from the host 4100. For example, the signals are based on the interfaces of the host 4100 and the SSD 4200. For example, the signals may be constructed according to at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) interfaces.

The plurality of memory devices 4221 to 422n includes a plurality of memory cells configured to store data. Each of the plurality of memory devices 4221 to 422n corresponds to one of the chip areas CHA of FIG. 1. The plurality of memory devices 4221 to 422n communicates with the controller 4210 through channels CH1 to CHn.

The auxiliary power supply 4230 is coupled to the host 4100 through the power connector 4002. The auxiliary power supply 4230 is supplied and charged with the power from the host 4100. The auxiliary power supply 4230 supplies power to the SSD 4200 when the power is not smoothly or continuously supplied from the host 4100. For example, the auxiliary power supply 4230 is located inside or outside the SSD 4200. For example, the auxiliary power supply 4230 may be disposed in a main board and supply auxiliary power to the SSD 4200.

The buffer memory 4240 functions as a buffer memory of the SSD 4200. For example, the buffer memory 4240 stores data received from the host 4100 or data received from the plurality of memory devices 4221 to 422n, or stores metadata such as mapping tables of the memory devices 4221 to 422n. The buffer memory 4240 includes volatile memories such as DRAM, SDRAM, DDR SDRAM, and LPDDR SDRAM, or non-volatile memories such as FRAM, ReRAM, STT-MRAM, and PRAM.

According to an embodiment of the present disclosure, by improving a process of forming a chip guard, stress imposed on a semiconductor device may be reduced by the chip guard.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor device comprising:
a semiconductor chip; and
a first chip guard around the semiconductor chip;
wherein the first chip guard comprises:
a plurality of pillars arranged in a first direction and extending in a second direction crossing the first direction;
a first projection extending from the plurality of pillars in the first direction; and
a second projection extending from the plurality of pillars and spaced apart from the first projection in the second direction.

2. The semiconductor device of claim 1, wherein the first chip guard surrounds the semiconductor chip.

3. The semiconductor device of claim 1, wherein the first projection couples the plurality of pillars in the first direction; and
wherein the second projection couples the plurality of pillars in the first direction.

4. The semiconductor device of claim 1, wherein a section of the first projection is between the plurality of pillars; and
wherein a section of the second projection is located between the plurality of pillars.

5. The semiconductor device of claim 1, wherein the first projection surrounds a section of each of the plurality of pillars; and
wherein the second projection surrounds a section of each of the plurality of pillars.

6. The semiconductor device of claim 1, wherein the second projection overlaps with the first projection in the second direction.

7. The semiconductor device of claim 1, wherein the plurality of pillars comprise:
a first pillar; and
a second pillar spaced apart from the first pillar in the first direction.

8. The semiconductor device of claim 7, wherein the first projection comprises:
a first ring extending from a side of the first pillar; and
a second ring extending from a side of the second pillar.

9. The semiconductor device of claim 8, wherein the second projection comprises:
a third ring extending from the side of the first pillar and overlapping with the first ring; and
a fourth ring extending from the side of the second pillar and overlapping with the second ring.

10. The semiconductor device of claim 1, further comprising a stack extending from a chip area into a guard area,
wherein the semiconductor chip is located in the chip area, and
wherein the chip guard is located in the guard area.

11. The semiconductor device of claim 10, wherein the stack comprises sacrificial layers alternately stacked with interlayer insulating layers in the second direction within the guard area.

12. The semiconductor device of claim 11, wherein the plurality of pillars extend through the stack in the second direction.

13. The semiconductor device of claim 11, wherein the first projection is located at a first level of a first sacrificial layer of the sacrificial layers, and the second projection is located at a second level of a second sacrificial layer of the sacrificial layers.

14. The semiconductor device of claim 11, wherein an outer surface of the first projection contacts a first sacrificial layer of the sacrificial layers; and
wherein a first surface of the first projection contacts a first interlayer insulating layer of the interlayer insulating layers and a second surface of the first projection contacts a second interlayer insulating layer of the interlayer insulating layers.

15. The semiconductor device of claim 11, wherein one of the interlayer insulating layers is located between the first and the second projection.

16. The semiconductor device of claim 1, wherein each outer surface of the plurality of pillars, each outer surface of the first projection, and each outer surface of the second projection include a curved surface.

17. The semiconductor device of claim 1, wherein an outer width of the first projection varies between a first width and a second width greater than the first width in a third direction; and
wherein the third direction is crossing the first direction and the second direction.

18. The semiconductor device of claim 17, wherein an outer width of the first projection varies between the first width and the second width.

19. The semiconductor device of claim 1, wherein the first chip guard comprises a conductive material.

20. The semiconductor device of claim 1, further comprising a second chip guard surrounding the semiconductor chip and the first chip guard.
